(19) United States
(12) Patent Application Publication
(10) Pub. No.: US 2012/0020018 A1
(43) Pub. Date: Jan. 26, 2012

(54) COMPONENT FOR A NOTEBOOK COMPUTER FOR RECEIVING EXTERNAL ANTENNAS

(76) Inventor: Edward Douglas Knapton, Spring, TX (US)

(21) Appl. No.: 13/259,258

(22) PCT Filed: Jun. 11, 2009
(86) PCT No.: PCT/US09/03549

§ 371 Date: Sep. 23, 2011

(51) Int. Cl. H05K 1/18; H05K 7/00

(52) U.S. Cl. 361/679.55; 361/748

(57) ABSTRACT

A component of a notebook computer and notebook computer system including an antenna jack configured to receive an external antenna. The component further includes a card including a receiver configured to receive signals from the external antenna, and a wire connecting the antenna jack to the card. The antenna jack is configured for receiving an external TV antenna or an external wireless network antenna.

### BACKGROUND

Notebook computers are designed to minimize size and weight to improve portability, while maximizing the capabilities of the computer. Because of the size requirements on a notebook computer, many components that could enhance the capabilities of the computer that are difficult to scale down in size are not available. Two features that are difficult to scale down in size include TV capabilities and Wireless Wide Area Network (WWAN) capabilities. TV and WWAN each require, ideally, large antennas. The antennas are typically significantly larger than common WiFi antennas due to the wavelength of the carrier waves. WiFi antennas are typically installed internally to the notebook. However, the increased size required for TV antennas and WWAN antennas requires reserving relatively large amounts of volume in the notebook computer for such internal antennas. Space could be saved internally, if external antennas are used as substitutes for internal TV or WWAN antennas. However, external antennas require input connections, and the input/output connector areas of notebook computers are limited. No previous method of incorporating WWAN and TV capabilities in the same notebook platform successfully solved the twin concerns of minimizing space restrictions and maximizing computer capabilities.

### BRIEF DESCRIPTION OF THE DRAWING

The following detailed description can be read in connection with the accompanying drawings in which like numerals designate like elements and in which:

FIG. 1 shows an exemplary embodiment of a computing system containing an external wireless network antenna or external TV antenna in which the same antenna jack and internal wiring can be used for either external antenna.

### DETAILED DESCRIPTION

To efficiently assemble notebook computers, and thus maintain the lowest possible cost for the manufacturer and end user, the manufacturer relies on a single standard platform for multiple different arrangements. These multiple arrangements are possible by having a connector for any planned arrangement present on every notebook computer regardless of whether the feature is used in the particular assembly. The combination of limited input/output connector areas, and efficient assembly using a single platform has frustrated efforts to provide end users with the option of choosing a WWAN capability or TV capability on the same notebook platform.

To enable a single notebook computer platform to include both WWAN and TV receiving capabilities, a method was developed to leverage an external TV antenna jack and accompanying internal wiring for use with an external antenna for electromagnetic waves used in a wireless network, such as WWAN. By utilizing one antenna jack and one set of wiring for multiple types of external antennas the notebook computer platform possesses additional capability while minimizing the space allocated for those purposes.

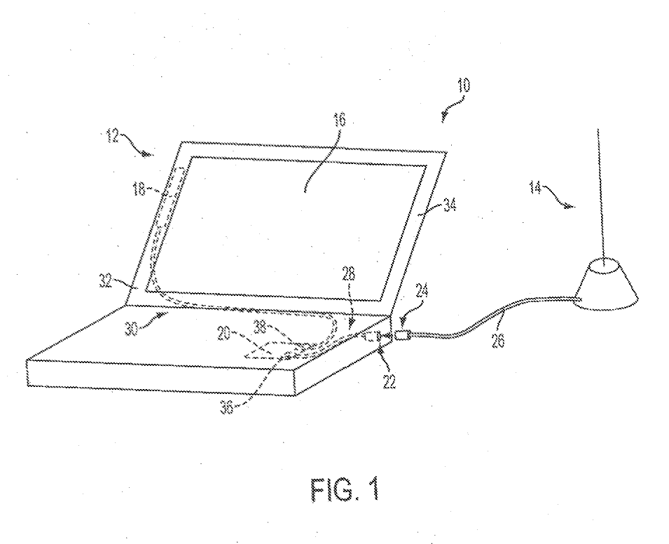

An exemplary embodiment of a computing system is shown in FIG. 1. The computing system 10 comprises a notebook computer 12 and an external antenna 14. The external antenna 14 is configured for receiving a certain type of electromagnetic wave. The external antenna can receive carrier waves for TV and/or wireless networks. Examples of wireless networks using different electromagnetic waves include Bluetooth, ZigBee, infrared based networks, WiFi, High Performance Radio Lan 2.0, Wireless Metropolitan Area Networks (WMAN), such as WiMAX, and WWAN. The antennas for these purposes on notebook computers can be incorporated internally or externally. Although internal antennas enhance portability of the notebook computer, the EMI field of the notebook computer create noise for the internal antennas. Further, some antennas are required to be rather large due to the wavelength of the carrier waves. Both TV and WWAN use rather large antennas.

The external antenna 14 is capable of connection to a notebook computer via an external antenna cord 26, which includes a plug 24 on the end of of the external antenna cord opposite the end connected to the external antenna 14. The external antenna cord 26 includes, for example, coaxial RF antenna cable. The plug 24 includes, for example, MCX, MMCX, F-jack connector.

The notebook computer 12 includes an: antenna jack 22 configured to accept the plug 24 from a plurality of different external antennas 14. In an exemplary embodiment, the antenna jack 22 is capable of connecting to both an external TV antenna and an external WWAN antenna. The antenna jack 22 includes, for example, MCX, MMCX, F-jack, PAL jack.

The notebook computer 12 further includes a first internal wire 28 connecting the antenna jack 22 to a card 20 for receiving and processing signals from an antenna. The first internal wire 28 is configured to transmit signals from a plurality of different external antennas 14 including TV signals and any wireless network signal. In an exemplary embodiment, the wireless network signal transmitted is from a WWAN antenna.

The card 20 is selected depending on the type of external antenna used in the particular assembly of the notebook computer. By using the same antenna jack 22 and first internal wire 28 for multiple types of external antenna, the same notebook computer can be assembled to have external wireless network capabilities or TV capabilities. In assembly, the only difference between the two configurations would be the card 20 and the external antenna 14, which should correspond. For example, the same notebook computer 12 can be configured for TV by installing a TV card or configured for WWAN by merely substituting a WWAN card for the TV card without changing any internal wiring or antenna jacks. Useful TV cards include, for example, ATSC, NTSC, DVB-T, Hybrid NTSC/ATSC, DVB-T. Further, useful WWAN cards include, for example, 3G wireless card of EV-DO, HSDPA, UMTS standards. The external TV antennas include, for example, HP external ATSC/DVB-T antenna for notebooks. The external WWAN antennas include, for example, HP external WWAN antenna for notebooks.

In a further embodiment, especially when configured for WWAN, the card 20 includes more than one receiver. The first receiver 36 receives the signal from the external antenna 14, while a second receiver 38 receives a signal from an internal WWAN antenna 18. The card 20 can also include at least a third receiver (not pictured) connected to at least an additional internal WWAN antenna (not pictured). When the card 20 is configured with more than one receiver, the card 20 is configured to select the strongest signal from each of the antennas to which the card is connected. This enables the strongest possible signal for the wireless connection in case one of the two antennas encounters interference or noise during use.

The notebook computer includes a display screen 16 with a first area 32 adjacent the side of a display screen 16 and a second area 34 adjacent the side of the display screen opposite the first area 32. The first area 32 and second area 34 can each contain an internal WWAN antenna. In the exemplary embodiment of FIG. 1, the notebook computer 12 contains only one internal WWAN antenna 18 located in the first area 32. A second internal wire 30 is run along the display screen to connect the internal WWAN antenna 18 to the second receiver 38 of the card 20. In further embodiments not pictured, the single internal WWAN antenna 18 or an internal WWAN antenna in addition to the internal WWAN antenna 18 may be located in the second area 34 with an accompanying internal wire to connect the internal WWAN antenna to a receiver of the card 20. The internal WWAN antennas include, for example, HP internal WWAN antenna for notebooks.

By incorporating at least one internal WWAN antenna and an external WWAN antenna capability in a notebook, the notebook has more flexibility for the end user. The internal antenna can be used alone in situations where portability is a high priority, whereas the external antenna can be plugged in to improve functionality and performance in low signal strength areas or when portability is not as critical.

Although described in connection with preferred embodiments thereof, it will be appreciated by those skilled in the art that additions, deletions, modifications, and substitutions not specifically described may be made without departure from the spirit and scope of the invention as defined in the appended claims.

What is claimed is:

1. A component for a notebook computer comprising:
A) an antenna jack configured to receive an external antenna;
B) a card including a receiver configured to receive signals from the external antenna; and
C) a wire connecting the antenna jack to the card,
wherein the antenna jack is configured for receiving an external TV antenna or an external wireless network antenna.

2. The component of claim 1, wherein the card includes more than one receiver for receiving signals from an antenna.

3. The component of claim 2, wherein at least two of the receivers are configured to receive Wireless Wide Area Network (WWAN) signals.

4. The component of claim 2, wherein the card is configured to select a signal from the antenna receiving the strongest signal.

5. The component of claim 2, wherein the wire is connected to one of the receivers.

6. The component of claim 5, wherein one of the receivers other than the one connected to the wire is connected to at least one internal Wireless Wide Area Network (WWAN) antenna.

7. The component of claim 6, wherein a third receiver on the card is connected to a second internal WWAN antenna.

8. The component of claim 1, wherein the antenna jack is a coaxial connector.

9. The component of claim 1, wherein the wire is a mini-coaxial radio frequency cable.

10. A computing system comprising an external Wireless Wide Area Network (WWAN) antenna or external TV antenna and a component for a notebook computer according to claim 1.

11. The computer system of claim 10, wherein the system comprises an external WWAN antenna.

12. The computer system of claim 10, wherein the system comprises an external TV antenna.

13. The computer system of claim 10, further comprising at least one internal WWAN antenna.

14. The computer system of claim 10, wherein the card includes more than one receiver for receiving signals from an antenna.

15. The computer of claim 14, wherein the card selects the best signal from the signals received from the antennas.
